(19) United States
(12) Patent Application Publication
(10) Pub. No.: US 2026/0100222 A1
(43) Pub. Date: Apr. 9, 2026

(54) MEMORY CIRCUITS WITH TRACKING CELLS AND METHODS FOR OPERATING THE SAME

(71) Applicant: Taiwan Semiconductor Manufacturing Company, Ltd., Hsinchu (TW)

(72) Inventors: Shun Yamaguchi, Hsinchu (TW); Takumi Hara, Hsinchu (TW); Yoshisato Yokoyama, Hsinchu (TW)

(73) Assignee: Taiwan Semiconductor Manufacturing Company, Ltd., Hsinchu (TW)

(21) Appl. No.: 18/905,637

(22) Filed: Oct. 3, 2024

(51) Int. Cl. G11C 11/419

(52) U.S. Cl. CPC G11C 11/419

(57) ABSTRACT

Memory circuits with tracking cells are provided. A memory circuit includes a memory array comprising a plurality of first memory cells. The memory circuit includes a tracking column comprising one or more second memory cells. Each of the second memory cells is coupled to a first metallization layer disposed on a first side of a substrate and a second metallization layer disposed on a second side of the substrate, the second side opposite to the first side. The second metallization layer is configured to receive, from the second memory cells, a level of an internal node of a memory node. The first metallization layer is configured to provide, to the second memory cells, at least one supply voltage.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory device including a memory controller, in accordance with some embodiments.

FIG. 2 illustrates a cross sectional view of a memory device, in accordance with some embodiments.

FIG. 3 illustrates a schematic diagram of a circuit for a write tracking, in accordance with some embodiments.

FIG. 4 illustrates an example layout configured to form the tracking circuit of FIG. 3, in accordance with some embodiments.

FIG. 5 illustrates a schematic diagram of a circuit for a write tracking, in accordance with some embodiments.

FIG. 6 illustrates an example layout configured to form the write tracking circuit of FIG. 5, in accordance with some embodiments.

FIG. 7 illustrates a schematic diagram of a circuit for write tracking, in accordance with some embodiments.

FIG. 8 illustrates an example layout configured to form the write tracking circuit of FIG. 7, in accordance with some embodiments.

FIG. 9 illustrates a schematic diagram of a circuit for a write tracking, in accordance with some embodiments.

FIG. 10 illustrates an example layout configured to form the write tracking circuit of FIG. 9, in accordance with some embodiments.

FIGS. 11, 12, 13, and 14 illustrate example layouts for write tracking circuits including a backside VDD contact, in accordance with some embodiments.

FIGS. 15, 16, 17, and 18 illustrate example layouts for write tracking circuits including frontside and backside VDD contacts, in accordance with some embodiments.

FIG. 19 illustrates an example block diagram of a memory device, in accordance with some embodiments.

FIG. 20 illustrates an example layout configured to form the memory device of FIG. 19, in accordance with some embodiments.

FIG. 21 illustrates an example block diagram of a memory device, in accordance with some embodiments.

FIG. 22 illustrates another example block diagram of a memory device, in accordance with some embodiments.

FIG. 23 illustrates yet another example of a block diagram of a memory device, in accordance with some embodiments.

FIG. 24 illustrates another example still of a block diagram of a memory device, in accordance with some embodiments.

FIG. 25 illustrates example waveforms of a write tracking cell, in accordance with some embodiments.

FIG. 26 illustrates example waveforms of a write tracking cell, in accordance with some embodiments.

FIG. 27 illustrates an example flow chart of a method for operating a memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

A static random-access memory (SRAM) device is a type of volatile semiconductor memory that stores data bits using bistable circuitry that does not need refreshing. An SRAM cell may be referred to as a bit cell because it stores one bit of information, represented by the logic state of two cross coupled inverters (e.g., a storage node and complementary storage node). Memory arrays include multiple bit cells arranged in rows and columns. Each bit cell in a memory array typically includes connections to a power supply voltage and to a reference voltage. Logic signals on bit lines control reading from and writing to a bit cell, with a word line controlling connections of the bit lines to the inverters. A word line may be coupled to the bit cells in a row of a memory array, with different word lines provided for different rows.

Each successive bit cell along a bit line or word line has a characteristic input capacitance, and each conductor leg (e.g., a part of bit line or word line) between bit cells has a resistance, leading to a signal propagation delay. The delay is longer for bit cells that are farther than others along signal paths beginning at the source of memory addressing and control signals, such as the outputs of address decoding gates and line drivers coupled at an edge of the memory array. The delay affects the time needed to access the bit cells and limits the highest frequency at which the memory can be operated. The time taken to access an SRAM bit cell, e.g., for a read/write operation, may vary due to several factors including the relative position of the accessed bit cell within the SRAM array. Reliable estimation of SRAM timing characteristics is important for ensuring consistency in system components and high system performance.

In this regard, various techniques have been proposed to provide timing tracking functionality for accurate, efficient monitoring of an SRAM device. Timing tracking enables determination of when a nominal memory cell finishes a read or write operation. For example, tracking cells, which are similar to the nominal memory cells that store data, are enlisted or repurposed to provide a signal for controlling the timing of memory operations. However, additional lines coupled with a memory cell can increase routing density, which can, in turn, lead to increased stray capacitance or decreased size of bit lines, word lines, or other components. Accordingly, providing the additional lines can cause tracking cells to vary somewhat from the nominal memory cells, or can cause a reduction performance and power efficiency for the nominal memory cells. However, by providing at least a portion of signals to the tracking cells via a backside metallization layer, tracking cells may maintain a similar layout as non-tracking cells, such that tracking cell behavior can more closely mirror the function of non-tracking cells.

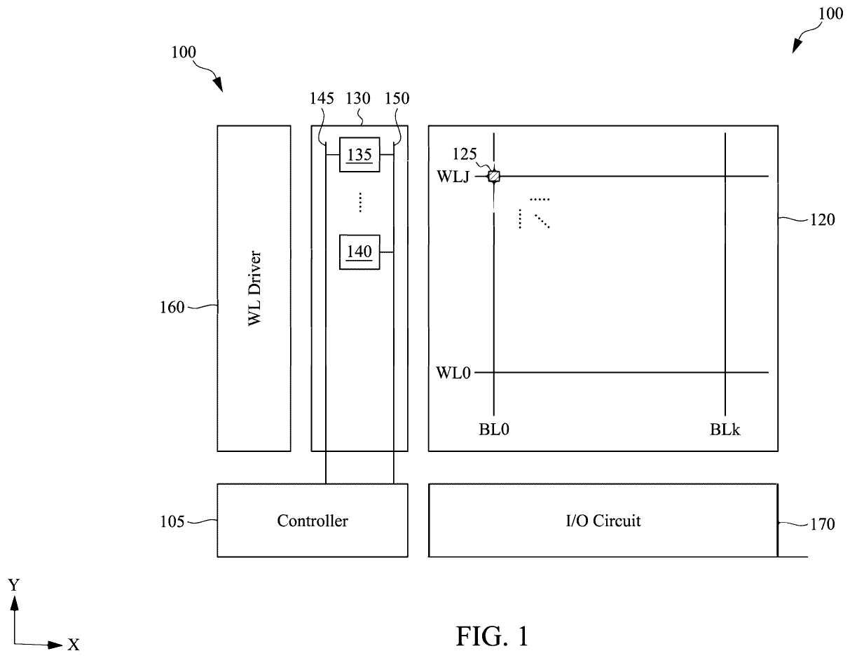

FIG. 1 illustrates a block diagram of a memory device 100, in accordance with various embodiments. The memory device 100 shown in FIG. 1 is simplified for illustration purposes, and thus, it should be appreciated that the memory device 100 can include any of various other components while remaining within the scope of the present disclosure.

As shown, the memory device 100 includes a memory controller 105 and a memory array 120. The memory array 120 may include a plurality of storage circuits or memory cells 125 arranged in two-or three-dimensional arrays. Each memory cell 125 may be coupled to one or more corresponding word lines (WLs) and one or more corresponding bit line (BLs). The memory controller 105 can write data to or read data from the memory array 120 according to electrical signals through word lines WL and bit lines BL. Further, according to various embodiments of the present disclosure, the memory controller 105 can adjust the pulse width of a WL signal conducted through a corresponding asserted word line WL based on the timing of a voltage level discharged through a tracking cell, which will be discussed in further detail below. In other embodiments, the memory device 100 includes more, fewer, or different components than shown in FIG. 1.

The memory array 120 is a hardware component that stores data. In one aspect, the memory array 120 includes a plurality of storage circuits or memory cells 125. The memory array 120 includes word lines WL₀ . . . WL_{J}, each extending in a first direction (e.g., the X-direction) and bit lines BL₀ . . . BL_{K}, each extending in a second direction (e.g., the Y-direction). In some embodiments, the memory array 120 may be referred to as having a number of columns and a number of rows, where each of the columns corresponds to a respective one of the bit lines BLs and each of the rows corresponds to a respective one of the word lines WLs. That is, the memory array 120 can include K columns and J rows of the memory cells 125. The word lines WL and the bit lines BL may be conductive metals or conductive rails. Each memory cell 125 is coupled to a corresponding word line WL and a corresponding bit line BL, and can be operated according to voltages or currents through the corresponding word line WL and the corresponding bit line BL.

In some embodiments, each bit line includes a bit line, BL and complementary bit line, BLB, coupled to one or more memory cells 125 of a group of memory cells 125 disposed along the second direction (e.g., the Y-direction). The bit lines, BL and BLB, may receive and/or provide differential signals. Each memory cell 125 may include a volatile memory, a non-volatile memory, or a combination of them. In some embodiments, each memory cell 125 is embodied as a static random-access memory (SRAM) cell or other type of memory cell. In some embodiments, the memory array 120 includes additional lines (e.g., select lines, reference lines, reference control lines, power rails, etc.).

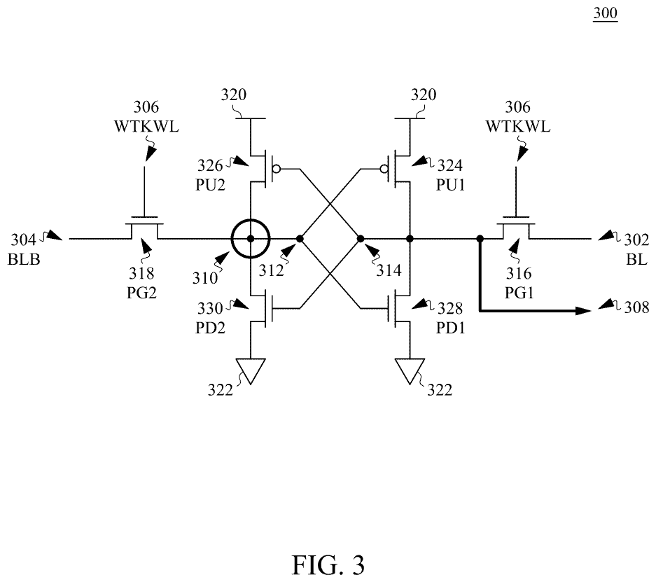

For example, the memory cell 125 may be is implemented as a six-transistor (6T) static random-access memory (SRAM) cell that consists of six transistors. Generally, the nominal memory cell 125 includes a pair of access or pass-gate transistors, PG1 and PG2, biased by (e.g., gated by) a corresponding word line WL. The pass-gate transistors PG1 and PG2 provide access to cross-coupled first and second inverters, respectively. The pass-gate transistors PG1 and PG2 can pass bit line signals to internal nodes of the cross-coupled inverters (referred to as a storage node and complementary storage node), when the WL signal fed into the gate terminals of the pass-gate transistors PG1 and PG2 is asserted. The first inverter includes a pull-up (e.g., PMOS) transistor PU1 and a pull-down (e.g., NMOS) transistor PD1, and the second inverter includes a pull-up (e.g., PMOS) transistor PU2 and a pull-down (e.g., NMOS) transistor PD2. The pass-gate transistors PG1 and PG2 respectively are coupled to a first bit line BL (“bit line”) and to a second bit line BLB (“bit line bar” or “bit line complement”). This configuration is referred to as a 6T (six-transistor) configuration, as is depicted henceforth, at FIGS. 3, 5, 7, and 9.

During a standby mode, the WL is not asserted, and thus the pass-gate transistors PG1 and PG2 disconnect the memory cell 125 from the bit lines, the BL and BLB. The cross-coupled inverters are coupled between two or more power supplies (VDD and VSS), and reinforce each other to maintain one of two possible logic states with a stored data bit at one of the internal nodes between the inverters (sometimes referred to as a node Q or node BL_IN) and the complement of that bit at the other node between the inverters (sometimes referred to as a node QB or node BLB_IN). During a read operation, the BL and BLB are pre-charged to a high logic state (e.g., a logic 1), and the WL is asserted. The stored data bit at the node Q is transferred to the BL, and the data bit at the node QB is transferred to the BLB. During a write operation, the value to be written is provided at the BL, and the complement of that value is provided at the BLB, when the WL is asserted. Although the 6T SRAM cells are herein described as an example implementation of the memory cell 125, it should be understood that the memory cell 125 can be implemented as other types of memory cells, including types of memory other than SRAM and other types of SRAM configurations than 6T (e.g., eight transistor (8T) or ten transistor (10T) configurations) while remaining within the scope of the present disclosure.

In addition to the memory cells 125 configured to store data (which are sometimes referred to as nominal memory cells 125), the memory device 100 may include one or more tracking columns 130 disposed next to or integrated into the memory array 120. For example, in FIG. 1, the tracking column 130 may be disposed along one of the edges of the memory array 120 that extend in parallel with the bit lines, BL₀ to BL_{K}. The tracking columns 130 can each include a number of tracking cells 135 and optionally include a number of dummy cells 140. Further, the tracking column 130 may include two types of tracking cells 135, one being configured to track a read operation performed on the nominal memory cells (sometimes referred to as a read tracking cell) and the other being configured to track a write operation performed on the nominal memory cells (sometimes referred to as a write tracking cell), in some embodiments. The tracking cells 135 and the dummy cells 140 may be configured in any respective numbers, while remaining within the scope of the present disclosure. In some embodiments, a total number of the tracking cells 135 and dummy cells 140 may be equal to the number of rows (J). For example, the number of tracking cells 135 may be selected to simulate a worst-case condition in a write and/or read operation.

In some embodiments, the tracking column 130 can further include one or more tracking word lines 145, and one or more tracking bit lines 150 (W/RTKBL). In accordance with the different (write and read) types of the tracking cells 135, the tracking column 130 may also include two types of tracking word lines, e.g., a write tracking word line (WTKWL) and a read tracking word line (RTKWL). The write tracking cell may be coupled to (or activated by) the write tracking word line, and the read tracking cell may be coupled to (or activated by) the read tracking word line. In general, each of the tracking cells 135 may be operatively coupled to a corresponding tracking word line 145, and operatively coupled to one or more corresponding tracking bit lines 150. However, each of the dummy cells 140 may not be operatively coupled to any tracking word line 145, but operatively coupled tot at least one corresponding tracking bit line 150.

For example, the tracking column 130 may include one tracking word line operatively coupled to a write tracking cell 135, one tracking bit line operatively coupled to the write tracking cell 135, and one complementary tracking bit line operatively coupled to the write tracking cell 135. In another example, the tracking column 130 may include one tracking word line operatively coupled to a write tracking cell 135 but not coupled to a dummy cell 140, one tracking bit line operatively coupled to the write tracking cell 135 and also coupled to the dummy cell 140, and one complementary tracking bit line operatively coupled to the write tracking cell 135 but not coupled to the dummy cell 140. In yet another example, the tracking column 130 may include one write tracking word line operatively coupled to a write tracking cell 135, one read tracking word line operatively coupled to a read tracking cell 135, one tracking bit line operatively coupled to both of the write and read tracking cells 135, and one complementary tracking bit line operatively coupled to the write tracking cell 135 but not to the read tracking cell 135. The tracking word line 145 and tracking bit line 150 are configured to conduct respective tracking signals, which will be discussed in further detail below. By conducting the tracking signals, the tracking word line 145 and tracking bit line 150 can respectively emulate signal routing delays in a functional memory array (e.g., 120) for a read or write operation at the far edge.

For example, the tracking word line 145 may include a (e.g., horizontal) portion extending along the rows of the memory array 120 (not expressly shown), and the (e.g., vertical) portion shown in FIG. 1 that extends along the columns of the memory array 120. A length of the vertical portion of the tracking word line 145 may be approximately equal to a height of the memory array (e.g., a distance from the memory controller 105 to the farthest tracking cell 135 or dummy cell 140, according to the orientation of the memory array in FIG. 1); and a length of the horizontal portion of the tracking word line 145 may be approximately equal to a width of the memory array 120 (e.g., a distance along any of the rows from one edge of the array to the other, according to the orientation of the memory array in FIG. 1). Accordingly, a sum of the lengths of the first and second portions of the tracking word line 145 may be such that the metal routing delay for accessing a cell at the top right corner of the memory array 120 is emulated, e.g., the delay from signal entry at the bottom left, propagating horizontally and vertically, over a path distance equal to the length of a path from one corner to the diagonally opposite corner.

Some tracking cells 135 do not function as the (nominal) memory cells 125 do in terms of storing data and supporting read/write operations. Rather, the tracking cells 135 may originally be a subset of the nominal memory cells 125 but be enlisted, or re-purposed, for timing tracking. For example, the tracking cells 135 can include bit cells with fixed logic values configured and coupled to one another so as to respond in a predictable way when addressed by test or tracking signals. Some non-limiting implementations of the tracking cell 135 will be discussed below. The dummy cells 140 aid in the matching of the capacitive and resistive environment for accurate modeling of nominal memory cell operation. Bit lines that are tracked typically have two factors that determine propagation delay of signals that are carried, namely serial resistance and parallel capacitance. The dummy cells 140 have real capacitive load, and mimic the capacitance of bit lines BLs coupled to the nominal memory cells. If the dummy cells 140 were not provided, the length of the tracking bit line would effectively appear to be shorter than the nominal bit lines BLs they are intended to emulate, which would decrease resistance and capacitance, and which might lead tracking circuitry to determine that read or write operations have concluded prematurely.

The memory controller 105 is a hardware component that is configured to control various operations of the memory array 120 such as, reading data bits from the memory cells 125, writing data bits into the memory cells 125, performing a tracking scheme on respective timings of the read/write operation, adjusting the tracking timings of the read/write operation, etc. In various embodiments, the memory controller 105 can include a number of circuits, each of which may be embodied as logic circuits, analog circuits, or a combination of them, to perform such operations.

As a representative example, the memory controller 105 can include a clock generator, a pre-charger, a tracking word line generator, and a buffer. In some embodiments, the clock generator can receive a clock (CLK) signal, and provide, based on the CLK signal, an internal clock (ICLK) signal with a rising edge. The rising edge is configured for a write driver (upon receiving a write enable signal) to perform a write operation on a nominal memory cell, for the pre-charger to cease pre-charging a write tracking word line coupled to a write tracking cell, to pull up a signal. In response to the write tracking word line signal transitioning to a logic 1, at least one corresponding write tracking cell can be activated, causing the voltage present at the storage node and complementary storage node to register a value provided by the bit line.

The memory controller 105 can provide a trigger (TRIG) signal through the buffer to the clock generator, in which the TRIG signal can closely follow the tracked write. Upon the TRIG signal being pulled up, the clock generator can pull down the ICLK signal, which causes the write operation (performed by the write driver) to cease. For example, the falling edge of the ICLK signal can cause a WL signal applied on a WL operatively coupled to the nominal memory cell to be pulled down. Stated another way, a pulse width of the WL signal can be adjusted based on the TRIG signal as based on the state transition of a tracking cell.

In some embodiments, the memory device 100 can further include various other circuit components such as, for example, a write (or WL) driver/controller 160, an input/output (I/O) circuit 170, etc., each of which may be embodied as logic circuits, analog circuits, or a combination of them. The write driver 160 can provide a voltage or current conducted through one or more word lines WL of the memory array 120. Such a voltage/current may sometimes be referred to as a WL signal. The memory controller 105 can utilize the adjusted ICLK signal to adjust the pulse width of this WL signal (as briefly discussed above). The I/O circuit 170 can sense a voltage or current conducted through one or more bit lines BLs of the memory array 120. For example, the I/O circuit 170 may include a number of sense amplifiers, each of which is operatively coupled to one or more of the bit lines BLs inside the memory array 120.

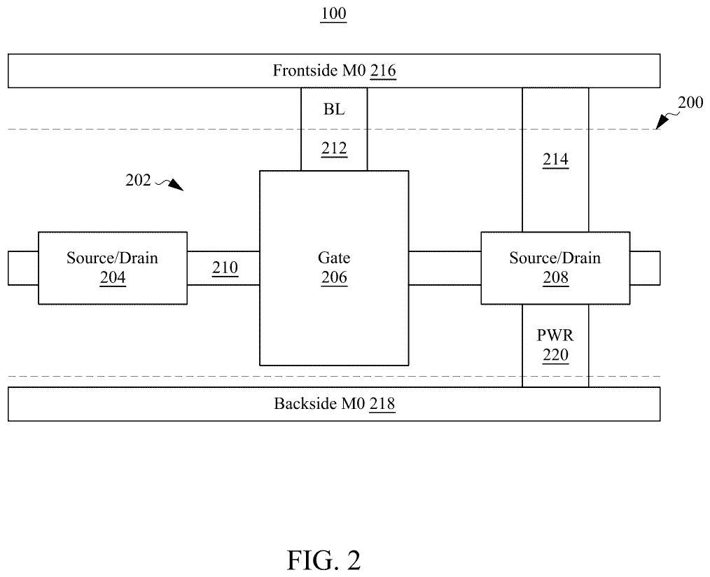

FIG. 2 illustrates a simplified cross-sectional view of a memory device 100, in accordance with some embodiments. An active surface 200 of the semiconductor device can include various components such as transistors 202, diodes, fuses, and so forth. Particularly, the depicted view includes a source 204, gate 206, and drain 208 of the transistor 202, as may be disposed on a diffusion column 210, fin array, or other portion of the active surface 200. The active surface 200 may be disposed over one surface of a semiconductive (e.g., silicon) substrate (sometimes referred to as a “front” of the substrate).

Via structures connecting a metallization layer to the active surface (sometimes referred to as contacts, such as frontside contacts) can include power supply inputs (e.g., VDD, VSS), word lines, tracking lines, or so forth. Such connections can couple components of a memory array 120 with a memory controller 105. For example, a bit line contact 212 can couple to a gate 206 of a transistor 202 while a VSS or VDD contact 214 can couple a source/drain to a corresponding supply voltage. The respective contacts 212, 214 can couple to various conductive elements of a metallization layer (e.g., a first metallization layer 216, also referred to as a M0 layer 216). The M0 layer 216 can, in turn, couple with an M1 layer, M2 layer, M3 layer, and so forth, to interconnect the various contacts, such as to couple tracking cells and nominal cells with a memory controller 105.

An opposite surface of the substrate (sometimes referred to as a “back” of the substrate) is, in many substrates, coupled with a heatsink or other package portion. However, provision of at least some signals to a backside of a device can aid improvements in device density, power delivery, and the like. As depicted, backside via structures connecting a backside metallization layer to the active surface (sometimes referred to as contacts, such as backside contacts) can include power supply inputs (e.g., VDD, VSS), word lines, tracking lines, or so forth. A first of the backside metallization layers (also referred to as a BM0 layer 218) can couple with further BM layers such as a BM1 layer, BM2, layers, or so forth. For example, a write tracking word line (WTKWL) contact 220 can couple a BM0 layer 218 to the active surface 200.

Backside power or signal delivery may be used in stacked 3DIC or other packaging architectures. For example, signals can be passed to a backside of a device through a frontside connection (e.g., passed through the chip by a through silicon via (TSV)), from another chip coupled therewith, or from another source, so that various of the MX layers may be coupled to the BMX layers. In some embodiments, the backside metallization can be used to provide additional signals, relative to the frontside metallization (e.g., WTKWL or bit lines (WTKBL)), which can couple with a memory controller to assert or detect signals via such lines. In some embodiments, the backside metallization can be used to supplement signals provided via a frontside metallization such as supply voltages (e.g., VDD or VSS), or to provide additional supply voltage (e.g., VDD1, VDD2, and so forth).

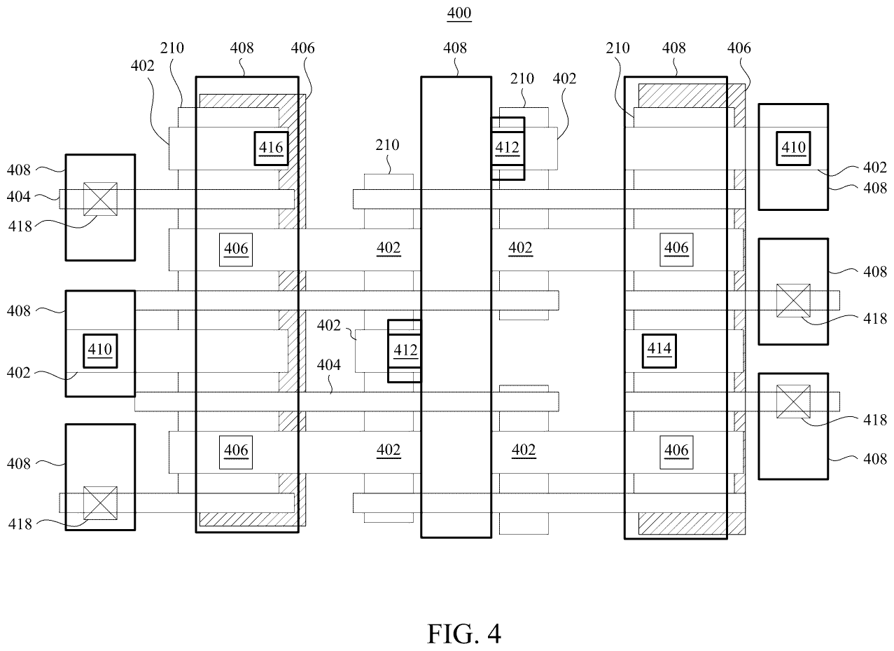

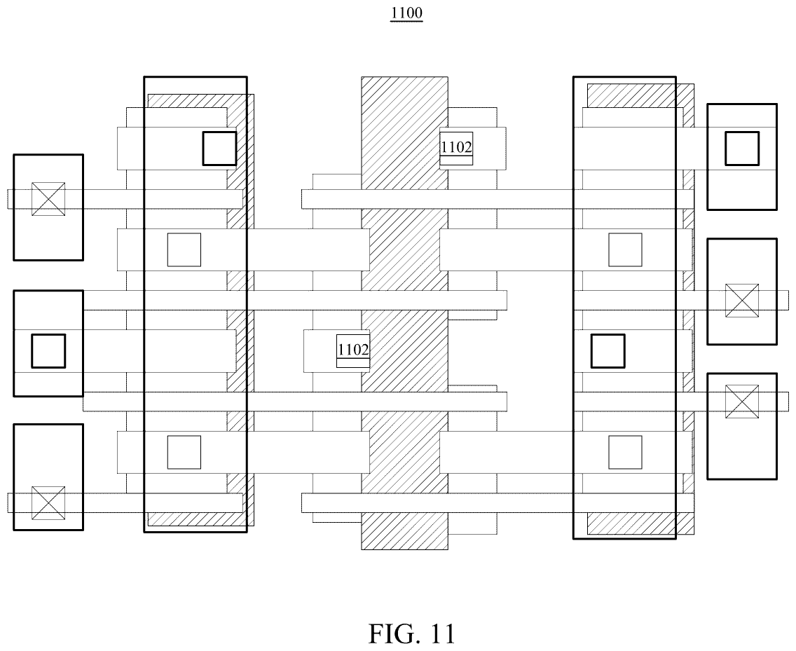

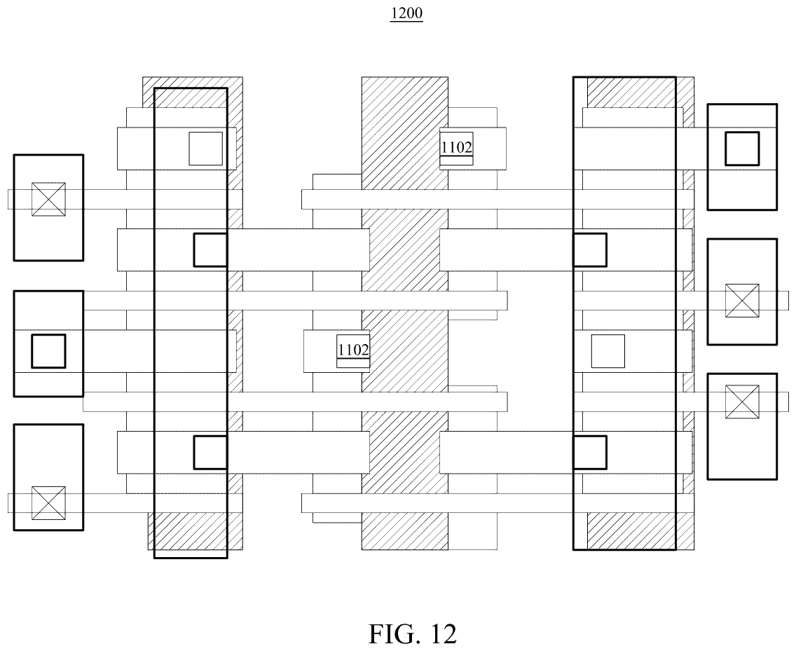

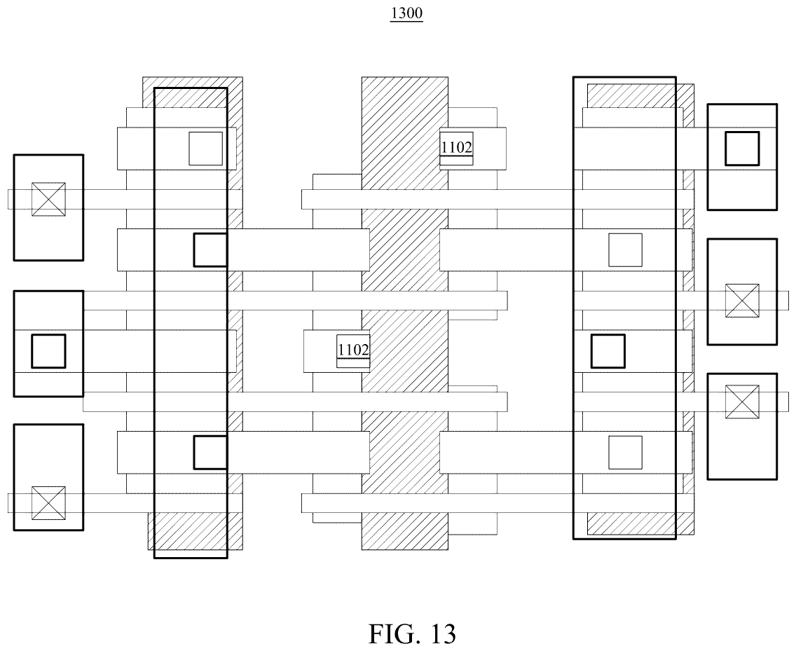

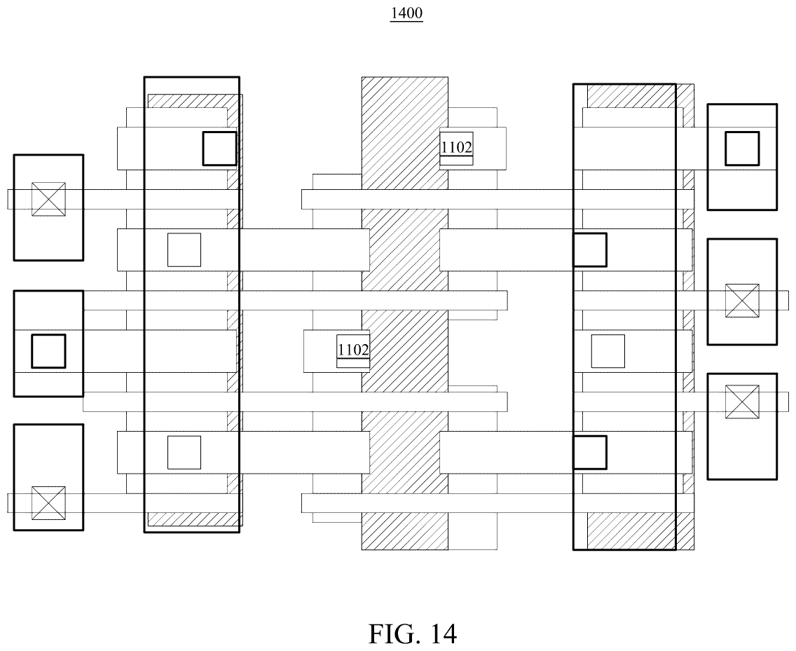

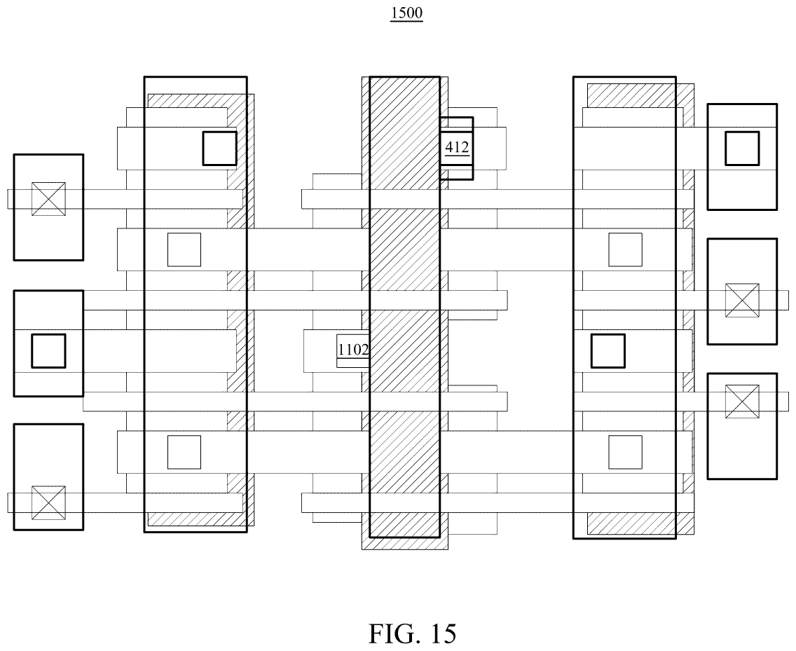

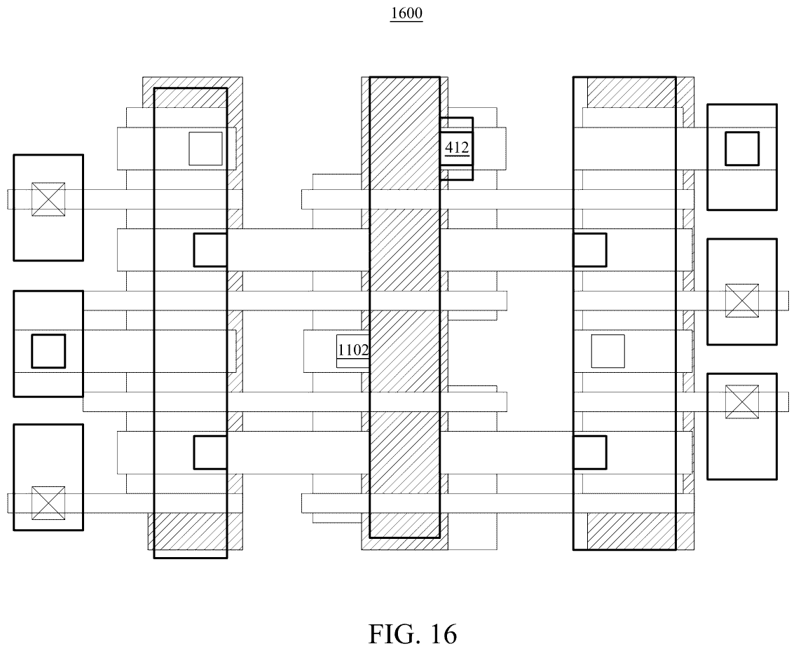

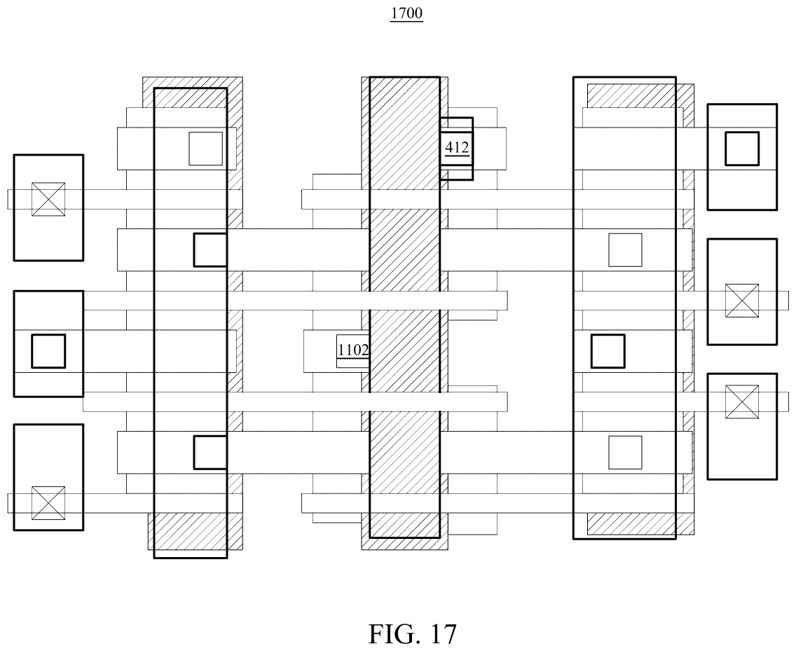

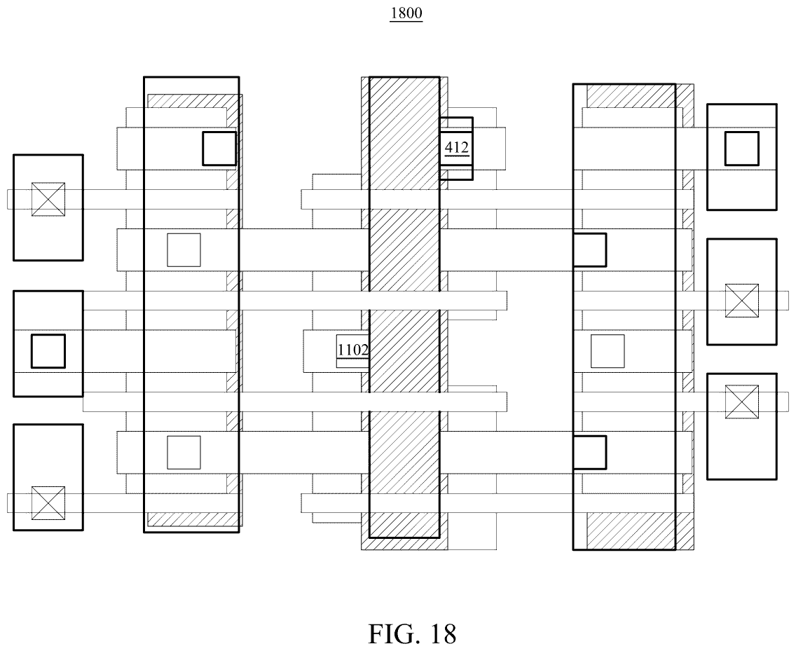

Referring generally to FIGS. 3, 5, 7, and 9 schematic diagrams of circuits including cross coupled inverters of a 6T SRAM memory cell connected to M0 layer 216 and BM0 layer 218 are provided. Referring generally to FIGS. 4, 6, 8, and 10, layouts corresponding to the schematic diagrams are provided. Thereafter, FIGS. 11-18, further layouts are provided, with FIGS. 11-14 providing examples of backside power delivery and FIGS. 15-18 providing examples of mixed-domain power delivery. Each of FIGS. 3-24 depict write tracking cells which use backside contacts for at least a portion of circuit interconnects. The use of these backside contacts can reduce density for a frontside of the circuits, such that the write tracking circuits can more closely approximate nominal cells. According to the better approximated cells, the memory controller can cause a memory device to operate with reduced timing margin or voltage margin. Such compressed margins may reduce device power or increase device performance relative to other approaches.

FIG. 3 illustrates a schematic diagram of a circuit 300 for write tracking, in accordance with some embodiments. For example, the circuit 300 can depict an SRAM bit cell of a write tracking column. A bit line 302 and complementary bit line 304 can provide values for storage to the cell, as gated by a word line (and particularly, a WTKWL 306 for the write tracking circuit). According to values provided via the bit lines 302, 304 and an assertion of the word line 306 (and more particularly, the WTKWL 306), a data value may be stored in a storage node 312 and complementary storage node 314 of the circuit. As indicated above, in a nominal bit cell, the respective storage nodes 312, 314 are not directly accessed, but can be measured according to an assertion of the word line 306 with the bit lines unasserted (e.g., in a high impedance state), so that the state of the storage nodes 312, 314 can drive the bit lines 302, 304 as may be read by the controller 105. Unlike a nominal memory cell, the storage of the value need not be “read” as intermated by pass-gate transistors, PG1 316 and PG2 318. Instead, a WTKBL (e.g., at least one of a first WTKBL 308 for a storage node 312 and a second WTKBL 310 for a complementary storage node 314) can be provided, to the controller 105 (e.g., can bypass PG1 316 and PG2 318). At least one of the first WTKBL 308 or second WTKBL 310 can be physically coupled with one of the M0 layer 216 or BM0 layer 218. Physical coupling can refer to the electrical coupling through a respective contact, rather than via a pass-gate transistor, wherein the signal is selectively coupled according to a state of a word line.

Each of the cross coupled inverters are shown as coupled with a pull up to a (same) VDD value 320 and pulled down to a (same) VSS value 322. Each of the VDD value 320 and the VSS value 322 are provided via a contact with M0 layer 216. That is, a PU1 transistor 324 and a PU2 transistor 326 are each coupled with a same supply voltage, VDD. A PD1 transistor 328 and a PD2 transistor 330 are each coupled with a same reference supply voltage VSS.

The first WTKBL 308 for a storage node 312 and a second WTKBL 310 for a complementary storage node 314 can couple to a memory controller via BM0 layer 218, such that other of the contacts and lines may couple to the memory controller via M0 layer 216. Accordingly, the write tracking circuit can use a same line layout as nominal bit cells, which may aid the write tracking circuit to approximate the function of the nominal bit cells (e.g., may exhibit similar capacitance, resistance, and so forth).

FIG. 4 illustrates an example layout 400 configured to form the write tracking circuit 300 of FIG. 3, in accordance with some embodiments. A fin array, diffusion column 210, or other structure can couple with various source/drain structures 402 gated by various gate structures 404. Further depicted are various backside conductive elements 406 and frontside conductive elements 408, which can include respective M0 layer 216 or BM0 layer 218, along with contacts therefor. Although additional layers (e.g., M1, M2, BM1, or BM2) are not depicted, it is understood that the conductive elements can include portions disposed at any number of the additional layers. For example, the leftmost contacts of the backside conductive elements 406 can be shorted together to provide a complementary storage node 314 connection and the rightmost contacts of the backside conductive elements 406 can provide a WTKBL 308 connection of a storage node 312.

Further contacts can couple with the M0 layer 216. Particularly, the M0 layer 216 can couple (e.g., directly couple or otherwise physically couple) with power supply contacts such as VSS contacts 410 and VDD contacts 412. Further of the depicted contacts coupled with the M0 layer 216 include a bit line contact 414, complementary bit line contact 416, and WTKWL contacts 418 for gates of pass-gate transistors PG1 316 and PG2 318 of each of the cross coupled inverters.

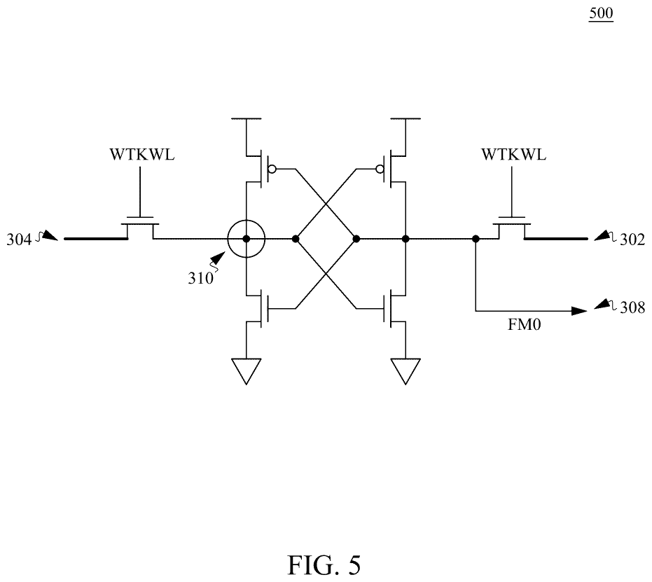

FIG. 5 illustrates a schematic diagram of a circuit 500 for write tracking, in accordance with some embodiments. According to the depicted circuit 500, the WTKBL 308, 310 connections are realized according to coupling with M0 layer 216. However, a density of the M0 layer 216 can be maintained according to a relocation of other connections to a BM0 layer 218. Particularly, the bit line 302 and complementary bit line 304 can coupled with (e.g., with the memory controller 105) via the BM0 layer 218.

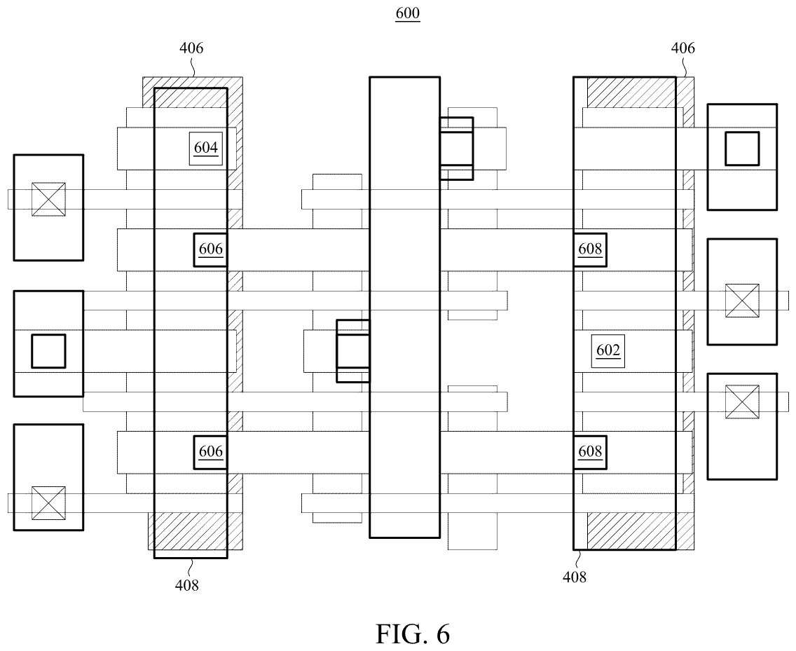

FIG. 6 illustrates an example layout 600 configured to form the write tracking circuit 500 FIG. 5, in accordance with some embodiments. Each of a bit line contact 602 and a complementary bit line contact 604 couple with a conductive element 406 of the BM0 layer 218. At least one complementary storage node contact 606 can couple with the M0 layer 216. In some embodiments, multiple contacts may be provided which can be shorted together at a backside conductive element 406 (e.g., at the M0 layer 216). Likewise, at least one storage node contact 608 can couple with the M0 layer 216; multiple of the storage node contacts 608 can be shorted together at a backside conductive element 406 of the M0 layer 216 or another layer coupled thereto (e.g., BM1 or BM2).

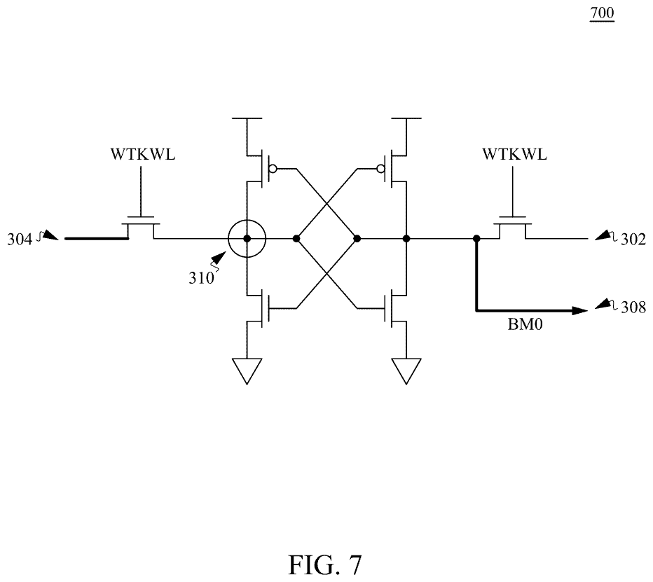

FIG. 7 illustrates a schematic diagram of a write tracking circuit 700, in accordance with some embodiments. A complementary bit line 304 can couple with a memory controller 105 via the BM0 layer 218 (as is depicted in FIGS. 5-6). A WTKBL 308 connection for the storage node 312 is realized according to coupling with a BM0 layer 218 (as is depicted in FIGS. 3-4). However, unlike the circuit 500 of FIGS. 5-6, the bit line 302 is coupled to the memory controller 105 via a M0 layer 216. Further, unlike the circuit 300 of FIGS. 3-4, the WTKBL 310 connection for the complementary storage node 314 is coupled with the memory controller via a M0 layer 216. Indeed, the present illustrative example is one of various implementations of particular connections provided herein as substituted or otherwise combined between the various aspects of the present disclosure.

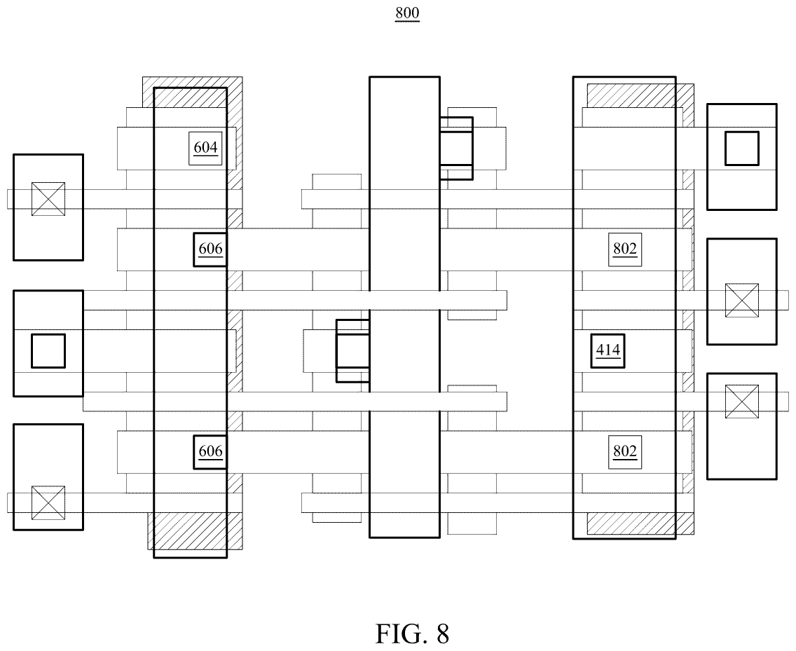

FIG. 8 illustrates an example layout 800 configured to form the write tracking circuit 700 of FIG. 7, in accordance with some embodiments. A complementary bit line contact 604 and at least one complementary storage node contacts 606 is provided as in FIG. 6 (coupled with the BM0 layer 218 and M0 layer 216, respectively). A WTKBL connection 308 (e.g., at least one WTKBL contact 802) of a storage node 312 and a bit line contact 414 can be provided as depicted in FIG. 4 (coupled with the BM0 layer 218 and M0 layer 216, respectively).

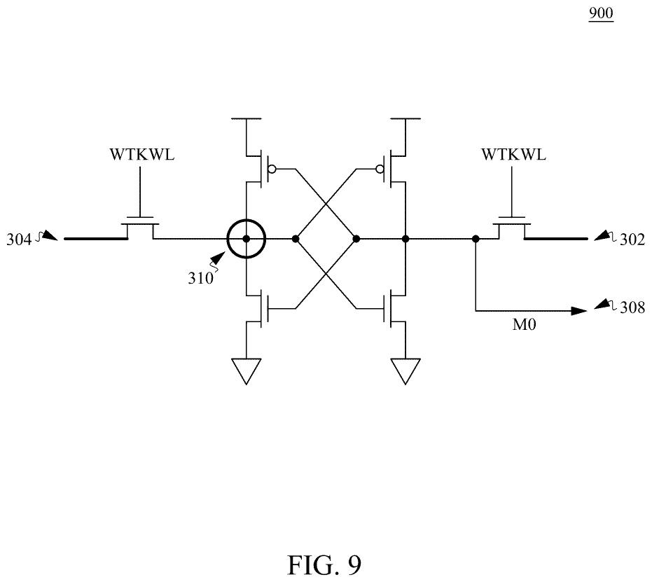

FIG. 9 illustrates a schematic diagram of a write tracking circuit 900, in accordance with some embodiments. The contacts implemented via the depicted circuit can invert the bit line and WTKBL implementation of FIGS. 7-8. That is, a bit line 302 and a WTKBL 310 connection for the complementary storage node 314 are realized according to coupling with a BM0 layer 218. A complementary bit line 304 and a WTKBL 308 connection for the storage node 312 are realized according to coupling to an M0 layer 216. That is, the frontside and backside contacts of FIGS. 8-9 are inverted relative to FIG. 8 for at least the bit lines 302, 304 and the WTKBL connections 308, 310.

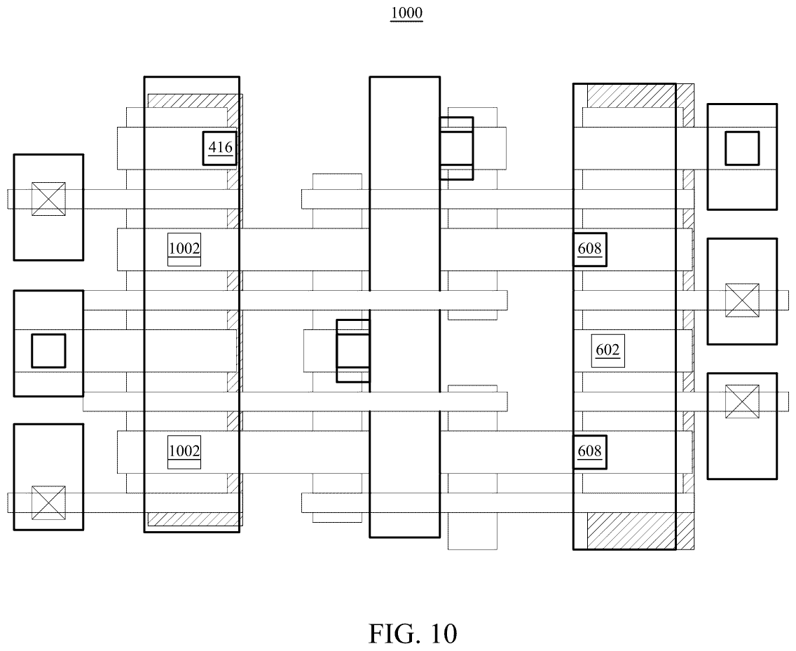

FIG. 10 illustrates an example layout 1000 configured to form the write tracking circuit 900 of FIG. 9, in accordance with some embodiments. A complementary bit line contact 416 and at least one complementary storage node contact 1002 is provided as depicted in FIG. 4. A bit line contact 602 and at least one storage node contact 608 is provided as depicted in FIG. 6.

FIGS. 11, 12, 13, and 14 illustrate layouts 1100, 1200, 1300, 1400 corresponding to the circuits of FIGS. 3, 5, 7, and 9, except that each VDD voltage is provided according to a connection between a VDD contact 1102 with the BM0 layer 218 rather than the M0 layer 216 (as is depicted in FIGS. 4, 6, 8, and 10). The memory controller 105 can use a separate VDD, relative to nominal cells, to adjust a voltage for the write (or read) tracking cells without impacting operation of nominal cells. For example, the memory controller 105 can adjust a supply voltage provided by the BM0 layer 218 to correlate an operation delay or state change of a WTKBL signal to a selected voltage. For example, the memory controller 105 can approximate the effects for distal or proximal cells, or approximate the effects of voltage or other variation according to an adjustment to the voltage. In some embodiments, the memory controller 105 can determine an operational margin according to an adjustment to a supply voltage for (read or write) tracking cells. For example, the memory controller 105 can operate tracking cells according to a somewhat lower voltage than nominal cells such that a detection of a fault of a tracking cell can provide an indication of available margin. The memory controller 105 can adjust a voltage or timing for nominal cells based on the available margin.

In some embodiments, the VDD voltage, as provided via the BM0 layer 218 may further couple with nominal cells. For example, a voltage supplied via the BM0 layer 218 may supplement or supplant a voltage depicted as provided via a contact physically coupled with the M0 layer 216.

FIGS. 15, 16, 17, and 18 illustrate layouts 1500, 1600, 1700, 1800 similar to the circuits of FIGS. 3, 5, 7, 9, 11, 12, 13, and 14. However, one VDD voltage (VDD1) is provided according to a connection with the BM0 layer 218 (as depicted in FIGS. 11, 12, 13, and 14) rather than the M0 layer 216. Another VDD voltage (VDD2) is provided according to a connection with the M0 layer 216 (as is depicted in FIGS. 4, 6, 8, and 10).

The memory controller 105 can independently adjust the supply voltage for the PU1 transistor 324 and the PU2 transistor 326. For example, the memory controller 105 can adjust the VDD1 and VDD2 voltages to mimic process variation within nominal memory cells, or to evaluate a rise and fall time, or other temporal offsets. Further, although the use of a BM0 layer 218 and M0 layer 216 may aid spatially constrained routing of mixed-domain power delivery such independent control of voltages is not limited to FIGS. 15-18. For example, in some embodiments, the memory controller 105 can separately control a VDD1 and VDD2 voltage wherein contacts for the VDD1 and VDD2 supply voltages both couple to a M0 layer 216, or both coupled to a BM0 layer 218.

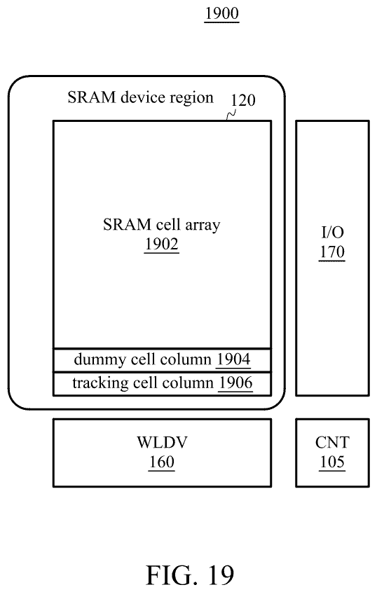

FIG. 19 illustrates an example block diagram of a memory device 1900, in accordance with some embodiments. A memory controller 105 is coupled with a word line driver 160 and an I/O circuit 170 which can store and retrieve data from bit cells of a memory array 120. The memory array 120 can include various memory columns, a portion of which (e.g., most) can include bit-cells for memory storage and retrieval. For example, a first portion 1902 of the memory array 120 can include such (nominal) bit cells. The memory array 120 can further include a write tracking cell column 1906, as may be intermediated from other bit-cells of the memory array 120 by another column, such as a read column or a dummy column 1904.

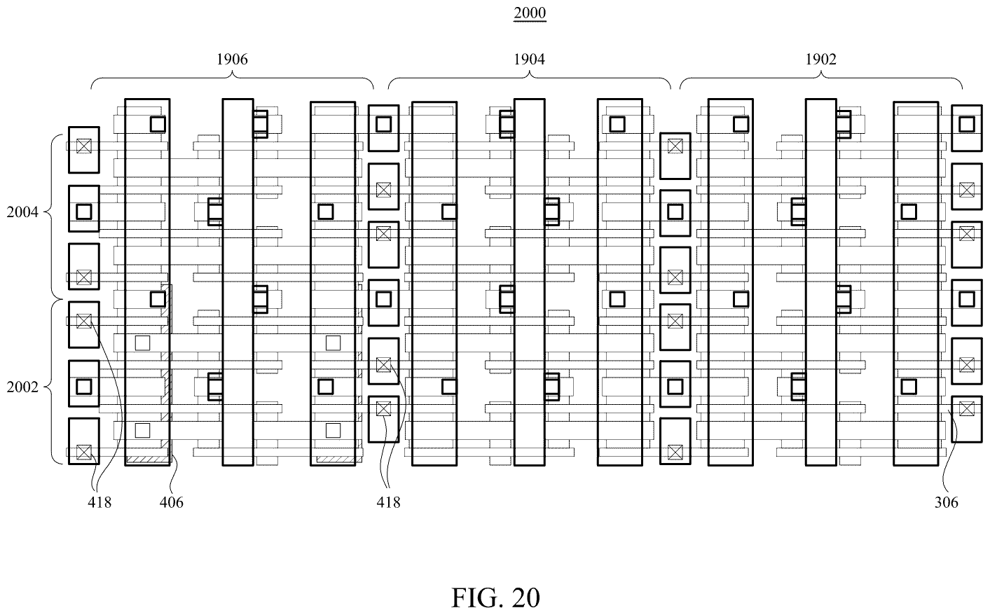

FIG. 20 illustrates an example layout 2000 configured to form the memory device of FIG. 19, in accordance with some embodiments. A write tracking cell column 1906 is disposed at an edge of the view, as may further be implemented along a physical edge of a memory array. Accordingly, WTKWL contacts 418 for gates of each of the cross coupled inverters may not interfere with operation of an adjacent column along one end of the write tracking cell column 1906. However, at an oppositive edge of the write tracking cell column 1906 (the edge abutting the dummy column 1904), WTKWL contacts 418 may abut the adjoining cell as may interfere with operation of the adjoining cell, because the WTKWL line (corresponding to the word line 306 of the first portion 1902 of the memory array 120) spans multiple columns. In some embodiments, a further dummy column 1904 can parallel the write tracking cell column 1906, as may better approximate stray capacitance of memory cells of the first portion 1902 of the memory array 120.

The example layout 2000 includes at least one tracking row 2002 and, optionally, at least one non-tracking row 2004. For example, tracking and non-tracking rows can alternate or terminate according to a cut in the backside conductive elements 406. That is, a write tracking column 1906 can span a lesser distance than the first portion 1902 of the memory array. A bit cell of a non-tracking row 2004 can operate as a memory cell, as a read tracking cell, or, as is depicted, have a word line 306 tied to ground to disable the operation of the bit-cell.

Although not depicted for brevity of the disclosure, further layouts may be achieved by inverting the VDD contacts 412 for the M0 layer 216 and the and VDD contacts 1102 for the BM0 layer 218. Further, in some embodiments, various refence voltages can be selected, or a reference voltage can be provided according to either of the BM0 layer 218 or M0 layer 216 (as may be received from other layers coupled to terminal connections or die connections).

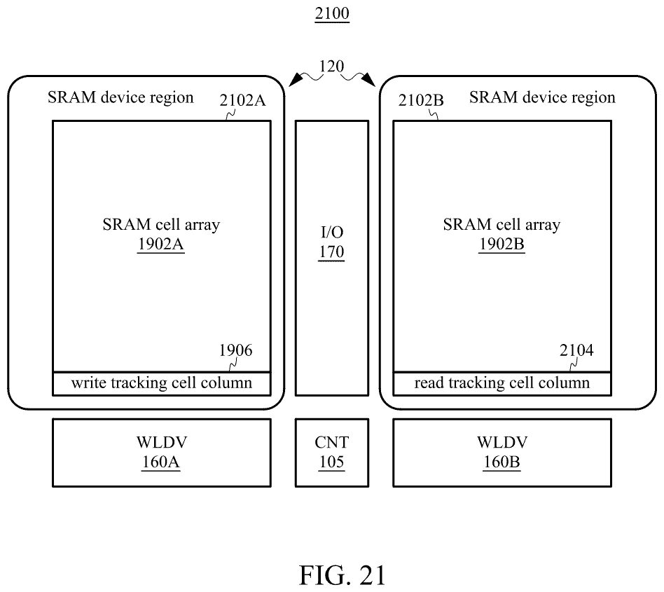

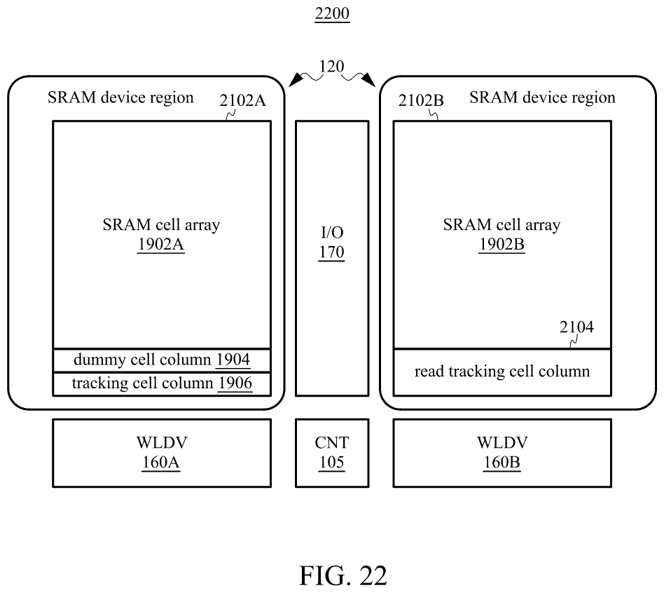

FIG. 21 illustrates an example block diagram of a memory device 2100, in accordance with some embodiments. The memory device 2100 includes multiple banks of a memory array 120 (as may sometimes be referred to as sperate memory arrays 120, without limiting effect). The memory controller 105 couples with a separate word line drivers 160A, 160B, and to an I/O circuit 170 coupled to separate banks. A first 2102A of the banks include a write tracking column 1906, as depicted in the single-bank implementation of FIG. 19. A second 2102B of the banks include a read tracking column 2104 to track reads according to an internal state of storage nodes and a value propagated to an output of a bit line. The depicted block diagram is not intended to illustrate every element of the memory device 2100. For example, at least the first bank 2102A can include a dummy column 1904 separating the write tracking column 1906 from a first portion 1902A of the first bank 2102A, in some embodiments. The second bank 2102B can omit a dummy column 1904 separating the read tracking column 2104 from a first portion 1902B of the second bank 2102B, according to differences between the read and write tracking cells (e.g., an omission of WTKWL contacts 418 shared between adjoining columns). Referring now to FIG. 22, another example block diagram for a memory device 2200 is provided, the block diagram including a dummy column 1904 as described above. Either of the memory device 2100 of FIG. 21 or the memory device 2200 of FIG. 22 can use a same multi-bank macro using a corresponding column for the write tracking column 1906 and read tracking column 2104.

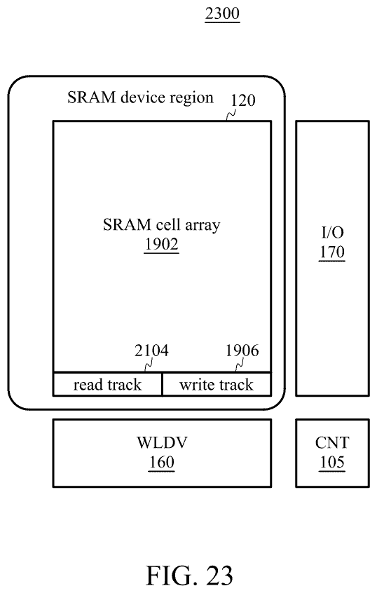

FIG. 23 illustrates an example block diagram of a memory device 2300, in accordance with some embodiments. As depicted, a single bank memory array 120 includes a write track 1906 and a read track 2104 disposed in a same column. For example, a conductive element coupled to the write track may be cut (e.g., omitted) for the read track 2104. Such an implementation may reduce an area of a memory array 120 for write tracking cells such that additional nominal memory cells may be incorporated into a same area, or the memory device 2300 may be implemented in a reduced area. A dummy column 1904 may be included (as is depicted in FIG. 21 or omitted (as is depicted in FIG. 22).

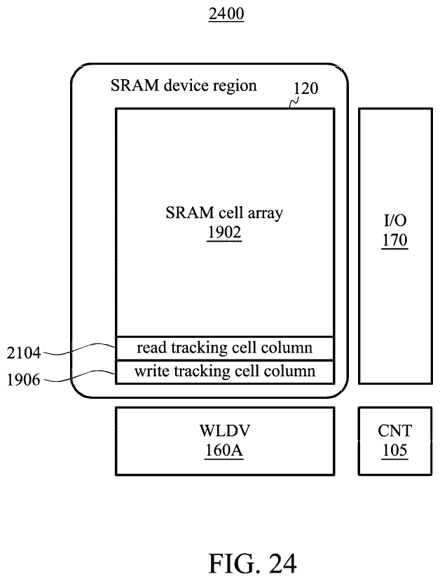

FIG. 24 illustrates an example block diagram of a memory device 2400, in accordance with some embodiments. The single-bank memory device 2400 includes a write tracking column 1906 and adjacent read tracking column 2104. For example, the adjacency of the read tracking column 2104 can obviate the need for a dummy column 1904 according to some routings of the MX or BMX layers. In some embodiments, various dummy columns 1904 can be included or omitted. For example, a dummy column 1904 can be included between the write tracking column 1906 and the read tracking column 2104, or between the read tracking column 2104 and the first portion 1902 of the memory array 120. Any such implementations can vary according to a particular routing of the memory array 120.

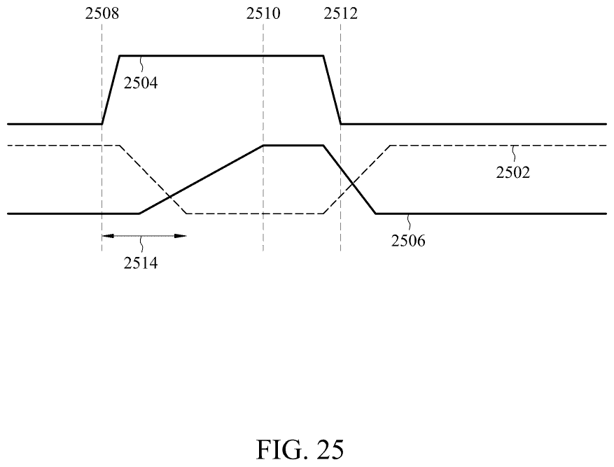

FIG. 25 illustrates example waveforms of a write tracking cell, in accordance with some embodiments. Depicted are a first waveform 2502 for a pre-charge voltage for a bit line voltage to prepare for a write, a second waveform 2504 for a write tracking word line voltage (WTKWL) to activate PG1 316 and PG2 318, and the bit-line voltage 2506 (WTKBL). At a first time 2508, with the bit line voltage 2506 pre-charged to an active high state, the WTKWL 2504 is asserted. Subsequent to the assertion of WTKWL 2504, the pass-gate transistors switch, and the storage node 312 begins to rise while the complementary storage node 134 falls to register the written information. Such operation can, at least somewhat, reduce the pre-charge voltage 2502 as charge migrated to the internal nodes of the memory device.

At a second time 2510, the memory cell completes a state transition associated with write. The state transition is depicted according to a maximum of voltage of WTKBL. However, in various embodiments, other threshold values may be used. For example, a voltage corresponding to about 0.5× or 0.9× of a maximum voltage may be selected as a transition edge according to particular characteristics of a manufacturing node of the memory array. Because such a voltage is reached sooner (as seen by the right end of the flip time mimic 2514 representation), a write time may be reduced, relative to the depicted interval until the third time. A memory controller an command such an adjustment for nominal bit-cells based on the monitored signals of the write tracking cell.

At a third time 2512, the WTKWL 2504 is de-asserted. However, the memory controller 105 can continue to monitor the state of the memory device (which may relax to zero according to an output of the memory controller 105 to prepare the tracking cell for a subsequent operation, or may leak current according to the presence of the WTKBL lines). A flip time mimic 2514 depicts an offset between the first time and the memory cell reaching a desired voltage (e.g., mimicking a registered state of a value for a nominal bit cell). For example, time subsequent to the flip in state of the memory cell can correspond to margin of the nominal memory cells, which can be compressed to increase performance or lower energy use (e.g., according to reduced pre-charge or reduced word line assertion times).

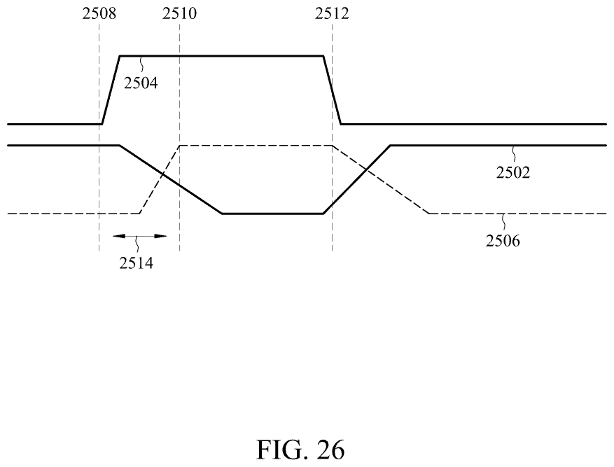

FIG. 26 illustrates example waveforms of a write tracking cell, in accordance with some embodiments. Depicted is an inverse state transition, relative to FIG. 25. For example, the inverse state transition can relate to another of a bit line or complementary bit line or opposite state transition of the memory cell generally. At the first time, the pre-charge 2502 is charged to zero, whereupon the WTKWL 2504 is asserted, causing the WTKBL to register zero, as achieved at the second time 2510, before being de-asserted at the third time 2512. A margin between the second time and the third time can vary from that of FIG. 25. A minimum margin can be used to select a voltage level in a single-domain power delivery circuit. Each margin can be used to select respective voltage levels for PU transistors 324, 326 in a mixed-domain power delivery circuit.

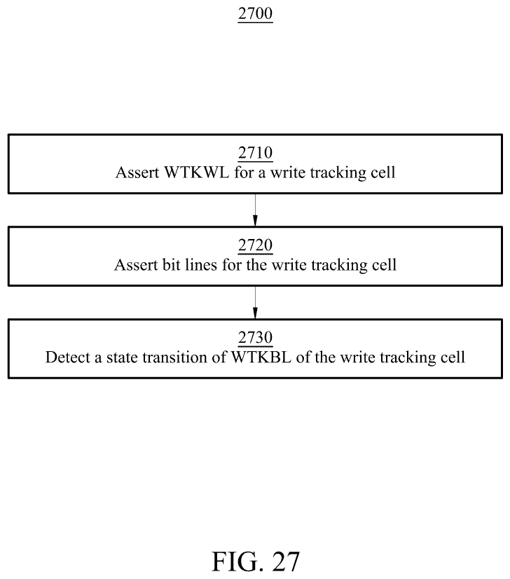

FIG. 27 illustrates an example flow chart of a method 2700 for operating a memory device, in accordance with some embodiments. For example, at least some of the operations of the method 2700 can be performed by a memory controller 105 interfacing with a circuit, layout, or block diagram as discussed with respect to FIGS. 1-26. Thus, in the following discussion of the method 2700, the reference numerals used throughout the present disclosure may be reused. It is noted that the method 2700 is merely an example and is not intended to limit the present disclosure. Accordingly, it is understood that additional operations may be provided before, during, and after the method 2700 of FIG. 27, and that some other operations may only be briefly described herein. The method 2700 is performed by a memory controller 105 of a device including at least one of a bit line 302, the complimentary bit line 304, the WTKBL, or a power supply input for the storage node or the complementary storage node as provided according to a BM0 layer 218 and another of such lines as provided by a M0 layer 216.

The method 2700 may start with operation 2710 of asserting a write tracking word line (WTKWL) for a write tracking row. For example, the assertion can switch pass-gate transistors into a conductive state to couple internal nodes of a memory device to bit lines. In some embodiments, the various operations of the present method may be re-sequenced, such as by asserting WTKWL subsequent to the assertion of the bit lines.

The method 2700 may proceed to operation 2720 of asserting a bit line and a complimentary bit line. The assertion can correspond to a change in state of the internal nodes. For example, a memory controller 105 can couple with the internal nodes via a write tracking bit line (WTKBL) to set the internal state of the internal nodes to an inverse state of the bit lines.

The method 2700 may proceed to operation 2730 of detecting a state transition of a write tracking bit line (WTKBL) corresponding to at least one of a storage node or a complementary storage node. For example, the detection of the state transition can include a detection of a temporal offset between the assertion of the bit line or the complimentary bit line and the detection of the state transition (e.g., corresponding to a position along the flip time mimic 2514 arrow of FIGS. 25-26). In some embodiments, the temporal offset is compared to a threshold value (e.g., one of various threshold values corresponding to a voltage or timing value of a look up table (LUT)).

The operations provided herein are not intended to be limiting. For example, operations can be added, omitted, substituted, or modified. For example, the method 2700 can include adjusting, responsive to the detection of the state transition, a value of a setup time, hold time, or operating voltage. In some embodiments, the method includes adjustments based on voltage levels of a mixed-domain power delivery circuit. For example, the method 2700 can include receiving, by the storage node and complementary storage nodes, different supply voltages (which may be received from the M0 layer 216, BM0 layer 218, or a combination thereof). A rising and falling edge of a WTKBL can be detected (e.g., the rising and falling edges corresponding to the cross coupled inverters of an SRAM memory cell). The memory controller 105 can adjust the timing or voltage value for nominal cells based on the first supply voltage, the second supply voltage, the rising edge detection, and the falling edge detection.

In one aspect of the present disclosure, a memory circuit is disclosed. The memory circuit includes a memory array comprising a plurality of first memory cells. The memory circuit includes a tracking column comprising one or more second memory cells. Each of the second memory cells is coupled to a first metallization layer disposed on a first side of a substrate and a second metallization layer disposed on a second side of the substrate, the second side opposite to the first side. The second metallization layer is configured to receive, from the second memory cells, a level of an internal node of a memory node. The first metallization layer is configured to provide, to the second memory cells, at least one supply voltage.

In another aspect of the present disclosure, a method for operating a memory circuit is disclosed. The method includes asserting a write tracking word line (WTKWL) for a write tracking row. The method includes asserting a bit line and a complimentary bit line for a write tracking cell of the write tracking row. The method includes detecting a state transition of a write tracking bit line (WTKBL) corresponding to at least one of a storage node or a complementary storage node. At least one of the WTKWL, the bit line, the complimentary bit line, the WTKBL, or a power supply input for the storage node or the complementary storage node is coupled to a front-side metallization layer. At least one of the WTKWL, the bit line, the complimentary bit line, the WTKBL, or the power supply input for the storage node or the complementary storage node is coupled to a back-side metallization layer.

In yet another aspect of the present disclosure, a system for data storage is disclosed. The system includes a memory array comprising a plurality of first memory cells. The system includes a tracking column comprising one or more second memory cells. Each of the one or more second memory cells is physically coupled to a first metallization layer disposed on a first side of a substrate and a second metallization layer disposed on a second side of the substrate, the second side opposite to the first side. The system includes a memory controller operatively coupled to the memory array and configured to identify a level of a first signal present on the second metallization layer. Each of the first memory cells comprise a storage node and a complementary storage node which is not physically coupled to the first metallization layer or the second metallization layer. At least one of a storage node or a complementary storage node of the tracking column is physically coupled to the first metallization layer or the second metallization layer.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory circuit, comprising:
a memory array comprising a plurality of first memory cells; and
a tracking column comprising one or more second memory cells, wherein each of the one or more second memory cells is coupled to a first metallization layer disposed on a first side of a substrate and a second metallization layer disposed on a second side of the substrate, the second side opposite to the first side;
wherein the second metallization layer is configured to receive, from the one or more second memory cells, a level of an internal node of a memory node, and the first metallization layer is configured to provide, to the one or more second memory cells, at least one supply voltage.

2. The memory circuit of claim 1, further comprising a controller configured to detect a state transition based on the level, wherein:
a storage node and a complementary storage node of the plurality of first memory cells are not physically coupled with the first metallization layer or the second metallization layer.

3. The memory circuit of claim 1, wherein at least one supply voltage input for each of the one or more second memory cells are provided via the second metallization layer, wherein the second metallization layer is a back-side metallization layer.

4. The memory circuit of claim 3, wherein at least two supply voltage inputs for the one or more second memory cells are provided via the back-side metallization layer.

5. The memory circuit of claim 3, wherein at least one supply voltage input is configured to provide a different supply voltage than a corresponding supply voltage input of the plurality of first memory cells.

6. The memory circuit of claim 1, further comprising:
a dummy column of dummy cells disposed between the tracking column and the memory array, the dummy column coupled to:
the tracking column via a shared write tracking word line (WTKWL); and
a first column of the memory array via a shared word line (WL).

7. The memory circuit of claim 6, further comprising:
a first bank comprising the dummy column, the memory array, and the tracking column, the tracking column configured as a write tracking column; and
a second bank comprising a read tracking column and a second memory array.

8. The memory circuit of claim 1, further comprising:
a first bank comprising the tracking column and the memory array; and
a second bank comprising a second tracking column and a second memory array.

9. The memory circuit of claim 1, further comprising, in a same bank:
the tracking column, configured as a write tracking column; and
a second tracking column, configured as a read tracking column.

10. The memory circuit of claim 9, wherein:
the tracking column and the second tracking column are disposed in a same column of a bank.

11. The memory circuit of claim 9, wherein:
the tracking column and the second tracking column are disposed in separate columns of a bank.

12. The memory circuit of claim 11, wherein:
the tracking column and the second tracking column are adjacent to one another, the tracking column and the second tracking column sharing:
a write tracking word line (WTKWL) with the tracking column; and
a word line with a first column of the memory array.

13. A method for operating a memory circuit, comprising:
asserting a write tracking word line (WTKWL) for a write tracking row; and
detecting a state transition of a write tracking bit line (WTKBL) corresponding to at least one of a storage node or a complementary storage node, wherein:
at least one of the WTKWL, the write tracking bit line, a complimentary bit line, the WTKBL, or a power supply input for the storage node or the complementary storage node is coupled to a front-side metallization layer; and
at least one of the WTKWL, the write tracking bit line, the complimentary bit line, the WTKBL, or the power supply input for the storage node or the complementary storage node is coupled to a back-side metallization layer.

14. The method of claim 13, further comprising:
adjusting, responsive to a detection of the state transition, a value of one or more of a setup time, a hold time, or an operating voltage for a memory array disposed on a same die as a write tracking cell.

15. The method of claim 14, wherein the detection of the state transition comprises a detection of a temporal offset between an assertion of the storage node or an assertion of the complementary storage node and the detection of the state transition.

16. The method of claim 15, further comprising:
comparing the temporal offset to a threshold value; and
selecting, from a look up structure, an adjusted timing value or voltage for the memory circuit.

17. The method of claim 15, comprising:
receiving, by the storage node, a first supply voltage;
receiving, by the complementary storage node, a second supply voltage different from the first supply voltage;
detecting a rising edge of the WTKBL;
detecting a falling edge of the WTKBL; and
adjusting the value based on the first supply voltage, the second supply voltage, a rising edge detection, and a falling edge detection.

18. A system for data storage, comprising:
a memory array comprising a plurality of first memory cells;
a tracking column comprising one or more second memory cells, wherein each of the one or more second memory cells is physically coupled to a first metallization layer disposed on a first side of a substrate and a second metallization layer disposed on a second side of the substrate, the second side opposite to the first side; and
a memory controller operatively coupled to the memory array and configured to identify a level of a first signal present on the first metallization layer or the second metallization layer, wherein:
each of the plurality of first memory cells comprise a storage node and a complementary storage node which are not physically coupled to the first metallization layer or the second metallization layer; and
at least one of the storage node or the complementary storage node of the tracking column is physically coupled to the first metallization layer or the second metallization layer.

19. The system of claim 18 wherein:
to detect a transition edge, the memory controller is configured to:
assert a signal via a first conductive element of one of the first metallization layer or the second metallization layer; and
detect a rising edge or falling edge via a second conductive element of one of the first metallization layer or the second metallization layer, subsequent to an assertion.

20. The system of claim 19 wherein the memory controller is configured to:
assert the second conductive element to set or reset a state of the storage node and the complementary storage node.
